(19) United States
(12) Patent Application Publication
(10) Pub. No.: US 2026/0082746 A1
(43) Pub. Date: Mar. 19, 2026

(54) DISPLAY DEVICE

(71) Applicant: AUO Corporation, Hsinchu City (TW)

(72) Inventors: Hui-Yuan Wang, Hsinchu City (TW); Yung-Da Chen, Hsinchu City (TW); Yung-Hsiang Lan, Hsinchu City (TW)

(73) Assignee: AUO Corporation, Hsinchu City (TW)

(21) Appl. No.: 19/204,602

(22) Filed: May 11, 2025

(30) Foreign Application Priority Data
Sep. 19, 2024 (TW) 113135478

(51) Int. Cl. H10H 29/34; H10H 29/41

(52) U.S. Cl. CPC H10H 29/34; H10H 29/41

(57) ABSTRACT

Provided is a display device, which includes a substrate, a first conductive layer, an insulating layer, a second conductive layer, multiple micro light emitting elements, and multiple micro control chips. The first conductive layer and the second conductive layer are configured on a surface of the substrate. The micro light emitting elements include a first micro light emitting element and a second micro light emitting element. The micro control chips include a first micro control chip and a second micro control chip. The first micro control chip is connected to the first micro light emitting element by the first conductive layer. The second micro control chip is connected to the second micro light emitting element by the second conductive layer. A vertical projection of the first micro control chip on the substrate and a vertical projection of the second micro light emitting element on the substrate overlap with each other.

### CROSS-REFERENCE TO RELATED APPLICATION

This application claims the priority benefit of Taiwan application serial no. 113135478, filed on Sep. 19, 2024. The entirety of the above-mentioned patent application is hereby incorporated by reference herein and made a part of this specification.

### BACKGROUND

### Technical Field

The disclosure relates to a display device.

### Related Art

A micro light-emitting diode display panel on the market may be configured with multiple micro light-emitting diodes and multiple control chips that control the micro light-emitting diodes on a substrate. In order to dispose the control chips on the substrate and maintain an equidistant arrangement between the micro light-emitting diodes, the distribution density of the micro light-emitting diodes is limited.

### SUMMARY

The disclosure provides a display device, which can be configured with multiple micro light emitting elements with a high distribution density, and a configuration margin of the display device is high.

According to an embodiment of the disclosure, a display device is provided, which includes a substrate, a first conductive layer, an insulating layer, a second conductive layer, multiple micro light emitting elements and multiple micro control chips. The first conductive layer is configured on a surface of the substrate. The second conductive layer is configured on the surface of the substrate. The insulating layer is positioned between the first conductive layer and the second conductive layer. The multiple micro light emitting elements include a first micro light emitting element and a second micro light emitting element. The multiple micro control chips include a first micro control chip and a second micro control chip. The first micro control chip is connected to the first micro light emitting element by the first conductive layer. The second micro control chip is connected to the second micro light emitting element by the second conductive layer. A vertical projection of the first micro control chip on the substrate and a vertical projection of the second micro light emitting element on the substrate overlap with each other.

Based on the above, the display device provided by the embodiment of the disclosure is configured with multiple micro light emitting elements on a same side of the substrate, and at least a portion of the micro light emitting elements are configured on the micro control chips, improving the distribution density of the micro light emitting elements in the display device and the configuration margin of the display device.

In order to make the features and advantages of the disclosure more comprehensible, the following examples are given and described in detail with the accompanying drawings as follows.

### BRIEF DESCRIPTION OF THE DRAWINGS

FIG. 1 is a schematic planar diagram of a display device according to some embodiments of the disclosure.

FIG. 2 is a schematic cross-sectional diagram of a display device according to a first embodiment of the disclosure.

FIG. 3 is a schematic cross-sectional diagram of a display device according to a second embodiment of the disclosure.

FIG. 4 is a schematic cross-sectional diagram of a display device according to a third embodiment of the disclosure.

FIG. 5 is a schematic planar diagram of a display device according to an embodiment of the disclosure.

### DESCRIPTION OF THE EMBODIMENTS

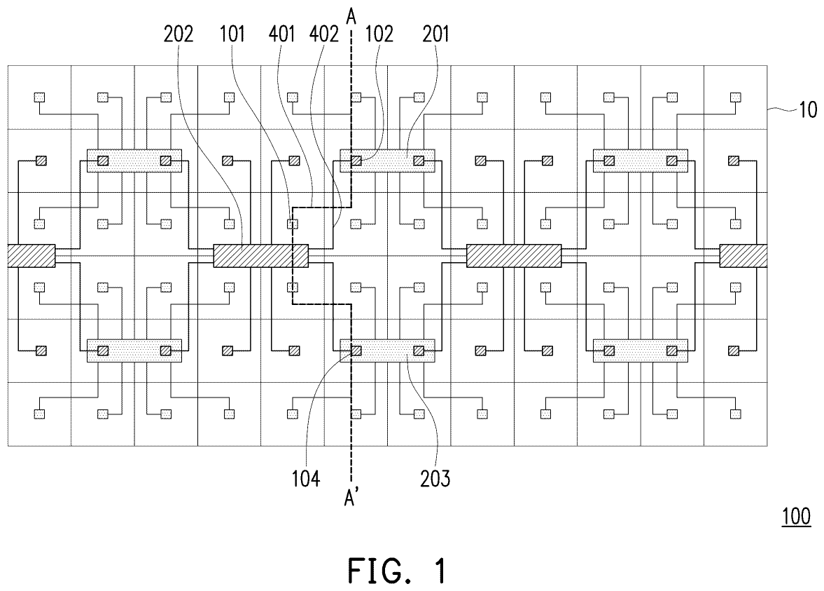

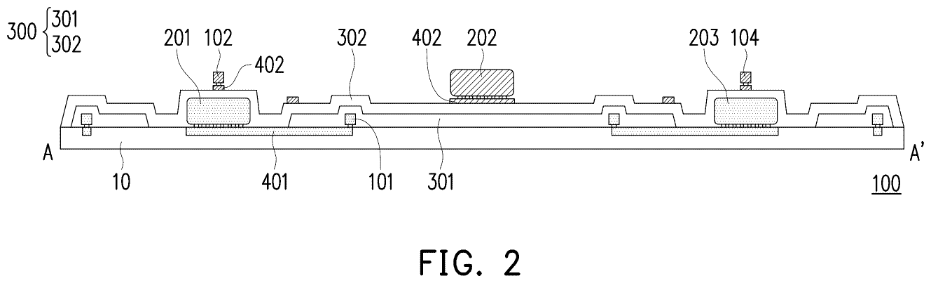

Referring to FIG. 1 and FIG. 2, FIG. 1 is a schematic planar diagram of a display device according to some embodiments of the disclosure, and FIG. 2 is a schematic cross-sectional diagram of a display device according to a first embodiment of the disclosure. In the first embodiment, FIG. 2 is a schematic cross-sectional diagram along line AA′ of FIG. 1.

In the first embodiment, a display device 100 includes a substrate 10, multiple micro light emitting elements, multiple micro control chips, a first conductive layer 401, an insulating layer 300, and a second conductive layer 402. The micro light emitting elements include a micro light emitting element 101 and a micro light emitting element 102. The micro control chips include a micro control chip 201 and a micro control chip 202. The insulating layer 300 includes a first insulating layer 301 and a second insulating layer 302.

The first conductive layer 401 and the second conductive layer 402 are both configured on an upper surface of the substrate 10. The insulating layer 300 is positioned between the first conductive layer 401 and the second conductive layer 402. The micro control chip 201 is connected to the micro light emitting element 101 by the first conductive layer 401. The micro light emitting element 101, the micro control chip 201, and the first conductive layer 401 are on a lower side of the insulating layer 300. The micro control chip 202 is connected to the micro light emitting element 102 by the second conductive layer 402. The micro light emitting element 102, the micro control chip 202, and the second conductive layer 402 are on an upper side of the insulating layer 300. Since the first conductive layer 401 and the second conductive layer 402 are on different sides of the insulating layer 300, a projection of the first conductive layer 401 on the substrate 10 may intersect with a projection of the second conductive layer 402 on the substrate 10, increasing a configuration margin of the display device 100.

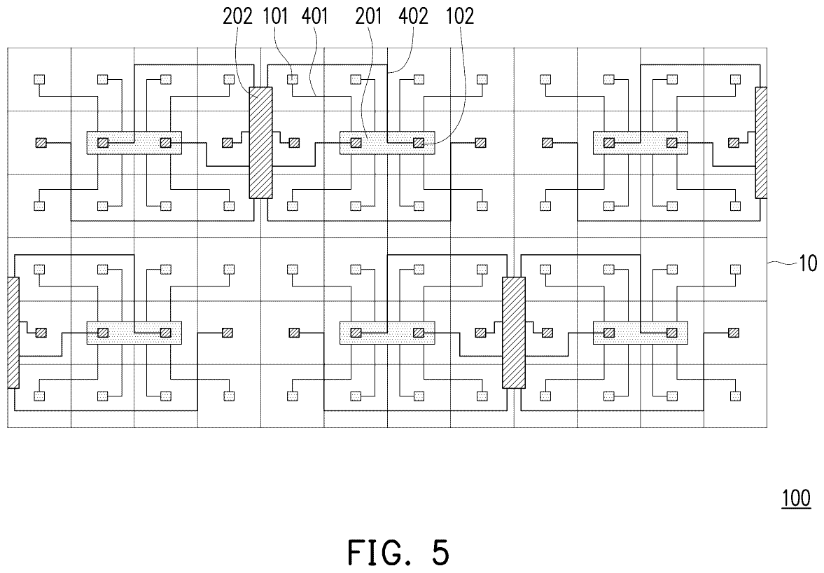

However, the disclosure is not limited thereto. In an embodiment, as shown in FIG. 5, a projection of the first conductive layer 401 connecting between the micro control chip 201 and the micro light emitting element 101 on the substrate 10 may not intersect with a projection of the second conductive layer 402 connecting between the micro control chip 202 and the micro light emitting element 102 on the substrate 10.

Also referring to FIG. 1 and FIG. 2, light-emitting surfaces of the micro light emitting element 101 and the micro light emitting element 102 are both on an upper side of the substrate 10, and are configured to emit light toward the upper side of the substrate 10. Since the insulating layer 300 covers the micro light emitting element 101 and does not cover the micro light emitting element 102, this leads to different light transmitting ratios between currents of the micro light emitting element 101 and the micro light emitting element 102. Therefore, the currents of the micro light emitting element 101 and the micro light emitting element 102 may be respectively controlled by the micro control chip 201 and the micro control chip 202 to compensate for a difference in light transmitting ratio caused by the insulating layer 300.

It should be noted that the micro light emitting element 102, as shown in FIG. 2, is configured on the micro control chip 201. In other words, a vertical projection of the micro light emitting element 102 on the substrate 10 and a vertical projection of the micro control chip 201 on the substrate 10 overlap with each other. Compared to the display device of prior art, which is configured with the micro light emitting element 101 on the substrate and is not configured with the micro light emitting element 102 on the micro control chip 201, the display device 100 provided in the embodiment is configured with the micro light emitting element 101 on the substrate 10 and configured with the micro light emitting element 102 on the micro control chip 201, effectively improving a distribution density of the micro light emitting elements in the display device 100.

In the first embodiment shown in FIG. 1 and FIG. 2, the display device 100 further includes a micro light emitting element 104 and a micro control chip 203. The micro light emitting element 104 is connected to the micro control chip 202, and the micro light emitting element 104 is disposed on the micro control chip 203. By respectively disposing the micro light emitting element 102 and the micro light emitting element 104 on the micro control chip 201 and the micro control chip 203, the distribution density of the micro light emitting elements in the display device 100 is effectively improved.

To fully describe various implementation aspects of the disclosure, other embodiments of the disclosure are described in the following. It must be noted here that the following embodiments use the reference numerals and part of the contents of the foregoing embodiments. The same numerals are used to denote the same or similar elements, and the description of the same technical content is omitted. For the description of the omitted parts, reference may be made to the foregoing embodiments, and thus the description is not repeated in the following embodiments.

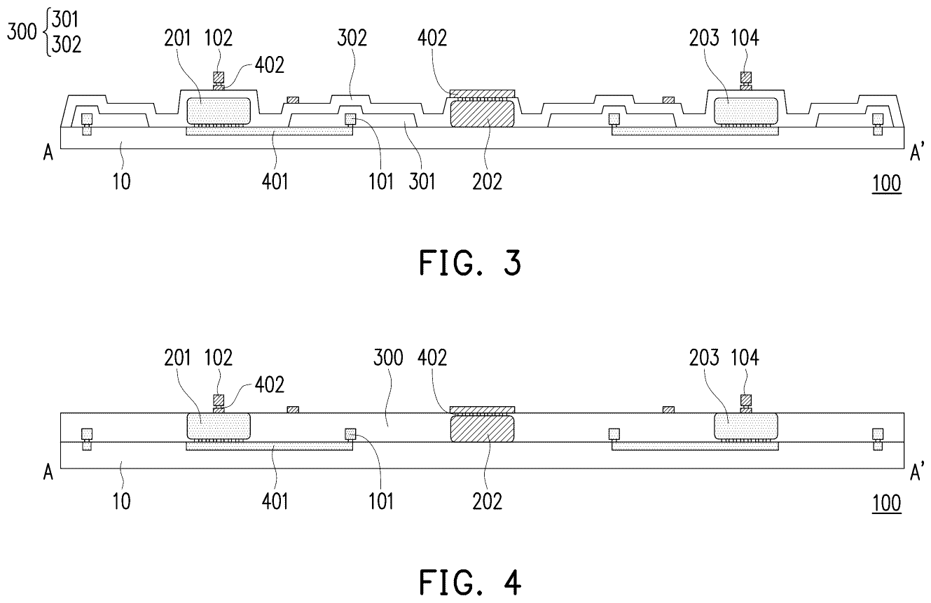

Referring to FIG. 1 and FIG. 3, FIG. 3 is a schematic cross-sectional diagram of a display device according to a second embodiment of the disclosure. In the second embodiment, FIG. 3 is a schematic cross-sectional diagram along line AA′ of FIG. 1.

In the second embodiment, the display device 100 includes the substrate 10, multiple micro light emitting elements, multiple micro control chips, the first conductive layer 401, the insulating layer 300, and the second conductive layer 402. The micro light emitting elements include the micro light emitting element 101 and the micro light emitting element 102. The micro control chips include the micro control chip 201 and the micro control chip 202. The second embodiment differs from the first embodiment in that both the micro control chip 201 and the micro control chip 202 are on the lower side of the insulating layer 300, and multiple electrodes of the micro control chip 202 may be connected to the second conductive layer 402 through holes formed through a photolithography process in the insulating layer 300, and connected to the micro light emitting element 102 by the second conductive layer 402.

Referring to FIG. 1 and FIG. 4, FIG. 4 is a schematic cross-sectional diagram of a display device according to a third embodiment of the disclosure. In the third embodiment, FIG. 4 is a schematic cross-sectional diagram along line AA′ of FIG. 1.

In the third embodiment, the display device 100 includes the substrate 10, multiple micro light emitting elements, multiple micro control chips, the first conductive layer 401, the insulating layer 300, and the second conductive layer 402. The micro light emitting elements include the micro light emitting element 101 and the micro light emitting element 102. The micro control chips include the micro control chip 201 and the micro control chip 202. The third embodiment differs from the first embodiment in that both the micro control chip 201 and the micro control chip 202 are on the lower side of the insulating layer 300, and multiple electrodes of the micro control chip 202 may be connected to the second conductive layer 402 through holes formed through a photolithography process in the insulating layer 300, and connected to the micro light emitting element 102 by the second conductive layer 402. The third embodiment further differs from the first embodiment in that a top surface of the insulating layer 300 away from the substrate 10 is a plane.

In summary, the display device provided by the embodiment of the disclosure is configured with multiple micro light emitting elements on a same side of the substrate, and at least a portion of the micro light emitting elements are configured on the micro control chips, improving the distribution density of the micro light emitting elements in the display device, and improving the configuration margin of the display device.

What is claimed is:

1. A display device, comprising a substrate, a first conductive layer, an insulating layer, a second conductive layer, a plurality of micro light emitting elements and a plurality of micro control chips, wherein
the first conductive layer is configured on a surface of the substrate,
the second conductive layer is configured on the surface of the substrate,
the insulating layer is positioned between the first conductive layer and the second conductive layer,
the plurality of micro light emitting elements comprise a first micro light emitting element and a second micro light emitting element,
the plurality of micro control chips comprise a first micro control chip and a second micro control chip, the first micro control chip is connected to the first micro light emitting element by the first conductive layer, and the second micro control chip is connected to the second micro light emitting element by the second conductive layer, and
a vertical projection of the first micro control chip on the substrate and a vertical projection of the second micro light emitting element on the substrate overlap with each other.

2. The display device according to claim 1, wherein a light-emitting surface of the first micro light emitting element and a light-emitting surface of the second micro light emitting element are on a same side of the substrate.

3. The display device according to claim 1, wherein the first micro light emitting element and the second micro light emitting element are on different sides of the insulating layer.

4. The display device according to claim 1, wherein the first micro control chip and the second micro control chip are on different sides of the insulating layer.

5. The display device according to claim 1, wherein the first micro control chip and the second micro control chip are on a same side of the insulating layer, and a plurality of electrodes of the second micro control chip are exposed by the insulating layer to be connected to the second conductive layer.

6. The display device according to claim 1, wherein a projection of the first conductive layer on the substrate intersects with a projection of the second conductive layer on the substrate.

7. The display device according to claim 1, wherein a projection of the first conductive layer on the substrate does not intersect with a projection of the second conductive layer on the substrate.

8. The display device according to claim 1, wherein the insulating layer covers the first micro light emitting element.

9. The display device according to claim 1, wherein the plurality of micro light emitting elements further comprise a third micro light emitting element, the plurality of micro control chips further comprise a third micro control chip, a vertical projection of the third micro light emitting element on the substrate and a vertical projection of the third micro control chip on the substrate overlap with each other, and the third micro light emitting element is connected to the second micro control chip.
